(19) United States
(12) Patent Application Publication
(10) Pub. No.: US 2023/0385473 A1
(43) Pub. Date: Nov. 30, 2023

(54) DATA CARRIER, TEST ENVIRONMENT, AND METHOD FOR SIMULATING AN EXPERIENCE OF COMFORT IN A ROOM IN A BUILDING

(71) Applicant: Fraunhofer-Gesellschaft zur Fõrderung der angewandten Forschung e.V., Munich (DE)

(72) Inventors: Daniel Neves Pimenta, Stuttgart (DE); Jan De Boer, Stuttgart (DE); Simon Wössner, Stuttgart (DE); Konstantinos Koutsomarkos, Stuttgart (DE)

(73) Assignee: Fraunhofer-Gesellschaft zur Fõrderung der angewandten Forschung e.V., Munich (DE)

(21) Appl. No.: 18/446,206

(22) Filed: Aug. 8, 2023

Related U.S. Application Data
(63) Continuation of application No. PCT/EP2022/052580, filed on Feb. 3, 2022.

(30) Foreign Application Priority Data
Feb. 8, 2021 (DE) 102021201127.6

(51) Int. Cl. G06F 30/13; G06F 30/20

(52) U.S. Cl. CPC G06F 30/13; G06F 30/20

(57) ABSTRACT

The embodiments simulate an experience of comfort in a room. A digital model A is created of the room and indoor and/or outdoor conditions Y_{R}, X_{R} which act on the room are defined. A first experience of comfort K_{R} is calculated for at least one location within the room. A test environment includes at least one actuator that acts on a subject. The state X_{MR} of the at least one actuator is changed such that a second experience of comfort K_{MR} of the subject in the test environment substantially corresponds to the first experience of comfort K_{R} at the one location within the room.

### CROSS-REFERENCE TO RELATED APPLICATIONS

This application claims priority as a Continuation of PCT/EP2022/052580, filed on Feb. 3, 2022, which claims priority to German Patent Application No. 10 2021 201 127.6 filed Feb. 8, 2021, the entirety of both applications are incorporated herein by reference.

### FIELD

The embodiments relate to a method for simulating an experience of comfort in a room. The invention also relates to a computer program for carrying out a method of this type and to a test environment for simulating an experience of comfort in a room.

### BACKGROUND

In practice, two-dimensional construction plans and three-dimensional architectural models are still used to visualize buildings. In addition, it is also a known practice to represent the rooms in a computer simulation. This can provide a realistic visual impression, for example in a virtual tour of the building.

However, it is not only the visual effect of colors and surfaces that plays a role in the experience of comfort of future users but also in particular the acoustic and thermal properties. However, the indoor climate, lighting conditions and acoustic properties can only be estimated by the planner. Future users and building owners must therefore base their decision mostly on qualitative statements made by the planner. Whether future users and building owners will later be satisfied with these conditions in the building can only be predicted with a certain degree of uncertainty.

### SUMMARY

Construction projects may be individual projects, i.e. a particular building is realized only once at a given location. Even if a building is constructed identically at different locations, the location and orientation will influence the experience of comfort within the building, for example, due to different site conditions or different uses. It is therefore difficult for both planners and future users to obtain a realistic impression of the future building during the planning phase.

There is a need to create a way to realistically and comprehensively assess the experience of comfort in a building as early as in the planning phase. In accordance with the invention, this object is achieved by the following embodiments.

According to the invention, a method and an apparatus for simulating an experience of comfort in a room are proposed. For this purpose, a digital model A of the room is created in the first step. In addition to geometric properties of the room or an entire building, the digital model A can also consider the location of the building and the relative orientation of individual outer walls and/or window openings. Furthermore, the digital model A can include properties of the different building materials used for windows, inner and outer walls or roof surfaces. In this way, for example, a sound permeability or a thermal transfer for different walls or subareas of walls or also for window elements, doors, roof surfaces or other components of the room or the building can be stored in the digital model. The digital model A can be stored on a computer, for example in a solid state memory or on a hard disk. The digital model A can be stored in full or in part in a database.

Subsequently, in the next step of the method, a vector of indoor conditions and/or outdoor conditions XR is defined, which act on the room or the building. Indoor conditions can include, for example, the location and temperature of heating elements, air conditioners, floor or panel heating systems, tiled stoves, cooling ceilings, humidifiers, dehumidifiers, or other devices that influence the indoor climate. Furthermore, in some embodiments of the invention, the indoor conditions of the room can include sound sources with indications of location, frequency, and intensity, such as people or musicians that are present or even machines to be operated in the future building or room. Lastly, indoor conditions can include lighting devices, which are placed at predeterminable locations of the digital model so that an illuminance, illumination spectrum, and/or direction of light incidence can be calculated for each subarea of interest of the room in the digital model. In some embodiments, olfactory stimuli can also be considered in the digital model, for example, cooking stoves, soldering stations, paint booths, or other devices associated with olfactory disturbance, such that odor disturbance by type and intensity can be calculated for each subarea of interest of the room in the digital model.

In some embodiments of the invention, outdoor conditions can also include noise sources, such as traffic routes or industrial plants located outside the building. In addition, the outdoor conditions XR can include climatic conditions, such as sun exposure, outdoor temperature, humidity, or precipitation. Lastly, the lighting conditions prevalent in the surroundings of the building can be considered, such as artificial light sources or shadow casting during the course of the year.

From the given indoor and outdoor conditions XR and the digital model A of the room, the objective physical conditions YR can then be determined for each location within the room or for a predeterminable location in the room to be evaluated. It is thus determined how the room or building modifies the outdoor and indoor conditions. For example, light, sound or heat can penetrate from the outside or thermal heat can be emitted from the room to the outside. Indoor sound or light can be reflected or absorbed and thus changed. Thus, a temperature, illuminance, and/or sound level can be calculated for at least one location within the room.

From the objective physical conditions YR prevalent for a predeterminable location of the room, a first experience of comfort KR can then be calculated for a user present at this location.

Furthermore, it is proposed according to the invention to provide a test environment having at least one actuator. The actuator can, for example, contain a heating or cooling panel which can be brought to a predeterminable temperature in response to an electrical open-loop and/or closed-loop control signal. In addition, the actuator can be selected from one or more monitors, VR glasses, MR glasses, and/or at least one light source. In addition, the at least one actuator can be selected from at least one loudspeaker and/or headphone. Lastly, the actuator can include one or more fans for generating an airflow. At least one other actuator can be set up to release gaseous or vaporous emissions, thus influencing humidity or releasing odors. The actuators of the test environment can be arranged in an open or closed enclosure that is configured to receive a subject in a standing, sitting, or lying position such that the actuators can act on the subject.

Then, the state of at least one actuator is influenced in such a way that a second experience of comfort KMR of the subject in the test environment substantially corresponds to the first experience of comfort KR at the at least one location within the digital model of the room. Thus, the subject is given an impression of the properties influencing the comfort in the planned building even before the building has been realized or planned modernization measures have been implemented. Only when the subject is satisfied with the experience of comfort KR in the room can the insights thus gained be considered during planning, such that the room can be created in such a way that the expectations of the user are met. For the purposes of the present invention, it is assumed in one embodiment that a second experience of comfort KMR of the subject in the test environment substantially corresponds to the first experience of comfort KR at the at least one location within the digital model of the room if the variables KMR and KR that express the respective experience of comfort differ from each other only by a predeterminable tolerance value. In another embodiment of the invention, it is assumed that a second experience of comfort KMR of the subject in the test environment substantially corresponds to the first experience of comfort KR at the at least one location within the digital model of the room if the objective physical conditions YMR and YR at the location of the subject that influence the respective experience of comfort differ from one another only by a predeterminable tolerance value.

In one embodiment of the invention, the test environment can be configured to simulate a thermal comfort or to let a user experience the thermal comfort. In another embodiment of the invention, the test environment can be configured to simulate an acoustic comfort or to let a user experience the acoustic comfort. In yet another embodiment of the invention, the test environment can be configured to simulate an acoustic and a thermal comfort or to let a user experience the acoustic and thermal comfort.

In one embodiment of the invention, it was recognized that due to the difference in geometry between the planned room or the planned building and the test environment, and due to the limited properties of the actuators, it is not sufficient to apply the objective physical conditions YR prevalent at a predeterminable location of the room 1:1 to the actuators of the test environment. For example, if a window area in a room cools down to a low value due to low outdoor temperatures, this may only influence the experience of comfort of the user to a small extent if the distance to the window is very large and/or the window area is very small. If the subject in the test environment would now be placed at a shorter distance in front of a cooling panel that has the same temperature as the window area, the subject would not have a realistic impression of the impact of the cold window surface on the room climate since the radiation interchange with the cold surface in the test environment would be much stronger than the radiation interchange with the actually existing window in the room. The invention considers this context by not applying the objective physical conditions YR of the room 1:1 to the test environment, but rather the experience of comfort KR resulting from the objective physical conditions YR. Through this application the limits resulting from the technical limitations of the actuators can be considered, such that the state of the at least one actuator is selected in such a way that the difference between the first experience of comfort KR and the second experience of comfort KMR is minimized.

In some embodiments of the invention, the first experience of comfort KR for at least one location within the room can be determined by multiplying the indoor and outdoor conditions by the digital model of the room to obtain the conditions prevalent within the room. The objective physical conditions YR of the room thus result from the relation YR=A.XR. In the next step, the conditions prevalent within the room can be multiplied by a digital comfort model B to obtain the first experience of comfort KR of the user in the at least one location of the room, i.e. KR=B.YR. This type of calculation can be made easily and quickly, thus rendering possible a real-time determination of the first experience of comfort KR in the virtual model of the building or room. This also allows a user to move around in the virtual room or to change devices of the room such as shading, window openings, lighting devices or heating and climate or outdoor conditions such as time of day or season in the virtual model and to experience in the test environment the changing impression of comfort that results from the changed conditions in the room.

Similarly, the second experience of comfort KMR can be calculated by multiplying the state of at least one actuator XMR by a digital model A of the test environment to obtain the objective conditions YMR prevalent in the test environment, i.e. YMR=A.XMR. In the second step, the second experience of comfort KMR of the subject can be determined by multiplying the objective conditions YMR prevalent in the test environment by a digital comfort model B, i.e. KMR=B.YMR. In this case, too, the second experience of comfort KMR can also quickly and easily be determined on the basis of the respective state variables XMR of the actuators, such that the actuators can be quickly controlled in such a way that the differences between the first experience of comfort KR and the second experience of comfort KMR are minimized. In this way, the subject can be given as realistic an impression as possible of the experience of comfort KR in the planned building.

In some embodiments of the invention, the digital comfort model B can be determined on the basis of real user experiences. In other embodiments of the invention, the digital comfort model B can consider one or more of the following influencing variables: A speech transmission index according to DIN EN IEC 60268-16 and/or a clarity level according to DIN EN ISO 3382-1 and/or a unified glare rating according to DIN EN 12464 and/or a daylight probability according to DIN EN 17037 and/or an operative room temperature according to DIN EN ISO 7730 and/or a radiation asymmetry according to DIN EN ISO 7730. Even though the experience of comfort KR, KMR is not a strictly measurable influencing variable, it can be used to achieve a good match with real-world conditions for the majority of the subjects.

In some embodiments of the invention, the conditions prevalent in the test environment can be captured by at least one sensor, the state XMR of at least one actuator being changed in response to the sensor signals such that the second experience of comfort KMR of the subject substantially corresponds to the first experience of comfort KR at the at least one location within the room. A sensor system of this type can replace or supplement the above described model-based control of the at least one actuator such that the at least one actuator can be controlled with greater accuracy and/or faster.

In some embodiments of the invention, the state XMR of at least one actuator can be retrieved from at least one conversion table according to the desired second experience of comfort KMR of the subject. Such a conversion table can be read out without further computational operations, such that the actuators can be controlled more quickly, which can result in a fast response to a change in the outdoor environmental conditions in the digital model of the room.

In some embodiments of the invention, the state XMR of at least one actuator according to the desired second experience of comfort KMR of the subject can be determined by an artificial intelligence. For example, a supervised learning model can be employed for this purpose, implementing a regression algorithm and using the state XMR of the actuator as a prediction.

In some embodiments of the invention, the subject can influence the indoor and/or outdoor conditions XR which act on the room. For example, the subject can choose the time of day or season at which he would like to simulate the experience of comfort in the room. In other embodiments of the invention, the subject can, in the digital model, e.g. open a window, influence the heating control, shade a window opening, or switch on/off a lighting device and experience the impact on the experience of comfort for himself and directly. In some embodiments of the invention, the subject can also move around in the digital room model and in this way learn about the experience of comfort in different locations.

In some embodiments of the invention, the method according to the invention can be implemented in a computer program configured to capture or import the digital room model, for example from a CAD program. In addition, the computer program can include at least one database storing properties of different building materials, different lamps, heating elements, window and door elements or other elements used in construction and providing them for creating the digital model A of the room. Lastly, the computer program can determine the subject's first and second experiences of comfort KR, KMR according to predetermined indoor and/or outdoor conditions and control the actuators of the test environment such that the difference is minimized. The computer program can be stored on a data carrier, provided for transmission via a computer network, or stored in the main memory of a microcontroller or computer.

The invention will be explained in more detail below by means of embodiments and drawings without limiting the general concept of the invention. In the drawings,

### BRIEF DESCRIPTION OF THE DRAWINGS

FIG. 1 shows an exemplary room and its thermal properties.

FIG. 2 shows a test environment according to the present invention for simulating the room shown in FIG. 1.

FIG. 3 shows simulation results within the test environment according to FIG. 2.

FIG. 4 illustrates the method according to the invention by means of a block diagram.

### DETAILED DESCRIPTION

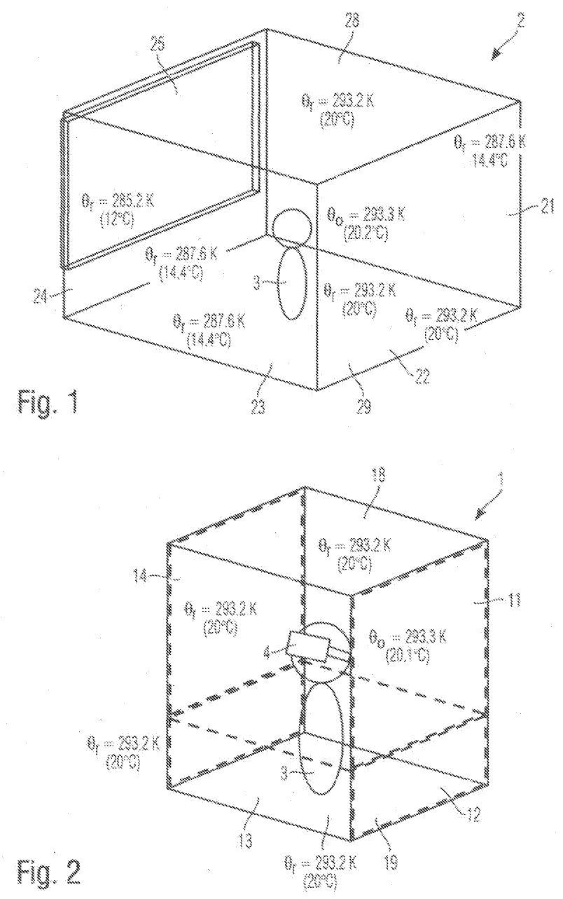

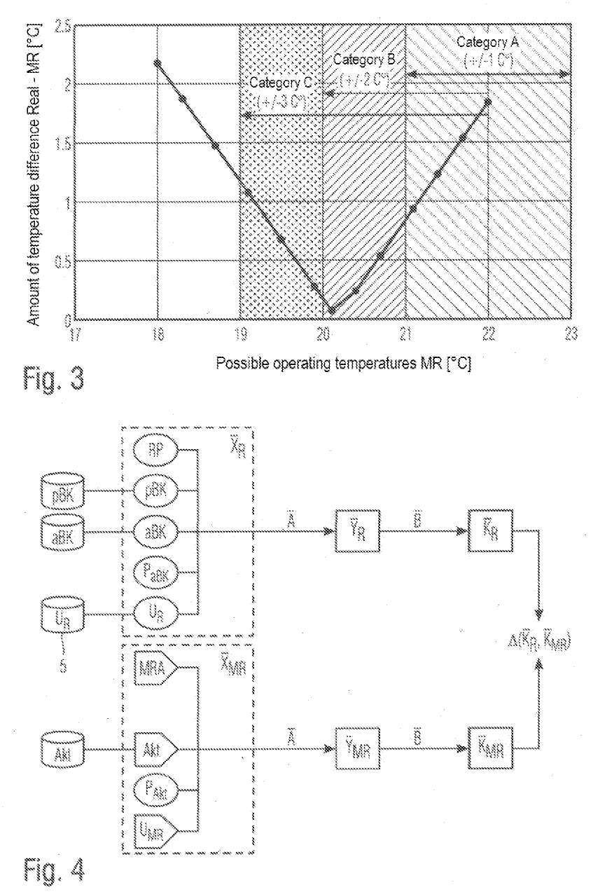

With reference to FIGS. 1 to 3, the invention is discussed by means of an exemplary embodiment. FIG. 1 here shows the digital model A of a room 2 in which a user or subject 3 is virtually present. FIG. 2 shows a test environment 1 which can be entered in reality by subject 3 and which provides them with the identical or at least similar experience of comfort as in room 2 if it were actually built according to the digital model. FIG. 3 illustrates the possible solution space or the possible differences between the first experience of comfort in room 2 and the second experience of comfort in test environment 1.

FIG. 1 shows a digital model of a room 2, which has four side walls 21, 22, 23 and 24. The outer walls 21, 23 and 24 are adjacent to the surroundings. The inner wall 22 is adiabatically connected to other parts of the building. The exterior building parts are not insulated and have lower surface temperatures than the other boundary surfaces for the case of winter considered. In the illustrated exemplary embodiment, a surface temperature of 14.4° C. is selected or calculated from the assumed outdoor temperature, the supplied heating energy and the U-value of the walls. In the illustrated exemplary embodiment, the inner wall 22 has a surface temperature of 20.0° C.

Furthermore, the digital model of room 2 includes a ceiling surface 28 and a floor surface 29, which are also adiabatically connected to other parts of the building and have a temperature of 20° C. each.

In the fourth side wall 24 there is a window 25 with a large surface area, which has insulating glazing not conforming to modern standards. In cold weather, the surface temperature of this glazing is therefore only 12° C. In the example, the air temperature in the room is 23.5° C. Air temperature and surface temperatures can be calculated from the outside temperature, the wall thickness, the degree of thermal insulation and/or the position, number and heating capacity of the heating elements.

The planner now wants to assess the thermal comfort in room 2. In addition, the planner would like to know what impact on thermal comfort is achieved by renovation or compare different variants of renovation. For example, the replacement of the window 25 with a modern window element of the same size or a reduction of the window opening while also replacing the window can be considered. In addition to thermal comfort, this variant also influences the visual impression of the room and the incidence of light. Unless the window 25 closes tightly, the impact of drafts can also be shown in the test environment 1. Lastly, the effect of insulating the facade or upgrading the heating system can be studied.

For this purpose, the thermal comfort of subject 3 is first calculated from the objective conditions at the location of the subject. The thermal comfort is influenced by the convective heat transfer between subject 3 and the air in the room as well as the exchange of radiant heat with the boundary surfaces of the room. Thus, the experience of comfort for subject 3 depends on the surface temperatures of the boundary surfaces 21, 22, 23, 24, 28, 29, and 25, as well as the air temperature in the room. In addition, the thermal comfort is influenced by drafts, radiation asymmetries, clothing insulation and activity level. For office rooms, for example, a perceived or operative temperature of 22° C. is recommended. For the surface temperatures shown in FIG. 1 and the assumed air temperature in the room of 23.5° C. (YR), an operative temperature θ0 of 20.2° C. is reached at the location of subject 3. This falls into category “B” of the experience of comfort KR.

Now, in order to give a subject an impression of the experience of comfort in room 2, the subject enters a test environment 1. In the illustrated exemplary embodiment, the test environment 1 is designed as a substantially cuboidal booth with four lateral boundary surfaces 11, 12, 13 and 14. In addition, the test environment 1 includes a floor 19 and a ceiling 18. The boundary surfaces 11, 12, 13, 14, 18 and 19 of the test environment 1 are at least partially equipped with heating or cooling panels, which can be brought to a predeterminable surface temperature. However, due to the varying distance of subject 3 to the respective cooling panels or side walls 11, 12, 13, 14, 18 and 19, on the one hand, and the distance of subject 3 from the boundary surfaces 21, 22, 23, 24, 25, 28 and 29 of room 2, on the other hand, it is not possible to identically apply the measured or calculated temperatures in room 2 as set points for the temperatures of the heating or cooling panels of the test environment 1. Instead, the experience of comfort of the subject in room 2 must be determined and the operative temperature in test environment 1 subsequently adjusted in such a way that the first experience of comfort KR in room 2 is as similar as possible to the second experience of comfort KMR in test environment 1. It should here also be considered that the test environment 1 can produce a different second experience of comfort KMR not only due to different distances, but also due to the type and number of actuators and the maximum or minimum temperatures that can be reached by the actuators.

According to the invention, it is therefore proposed to calculate in advance, in the form of a solution space

$$( \begin{matrix}\begin{matrix}\begin{matrix}{\overline{\overline{K}}}_{{MR}_{1}} \\ {\overline{\overline{K}}}_{{MR}_{2}}\end{matrix} \\ ⋮\end{matrix} \\ {\overline{\overline{K}}}_{{MR}_{i}}\end{matrix} ) ,$$

the possible second experiences of comfort KMR that

can be achieved by varying the control of the actuators.

For this purpose, considering the limitations of the actuators, the setup of the test environment, and the environment of the test environment, the achievable surface and air temperatures YMR in the test environment 1 and the respective resulting experiences of comfort KMR are determined for a subject 3 present in test environment 1.

In the illustrated exemplary embodiment, an operative temperature θ0 of 18; 18.3; 18.7; 19.1; 19.5; 19.9; 20.1; 20.4; 20.7; 21.1; 21.4; 21.7; or 22° C. can be generated at the location of subject 3. With respect to the required temperature for offices of 22° C., temperatures 19.1; 19.5; 19.9° C. fall into category C. Temperatures 20.1; 20.4; 20.7° C. fall into category B. Temperatures 21.1; 21.4; 21.7; 22° C. fall into category A. This solution space is shown in FIG. 3. Shown are the possible operative temperatures within the test environment 1 on the abscissa and the amount of the temperature difference between the test environment 1, on the one hand, and the operative temperature determined using the digital model of room 2, on the other hand, on the ordinate.

The operative temperature for the test environment 1 is then selected from the possible solution space using an optimization method such that it is as similar as possible to the first experience of comfort KR. In the illustrated exemplary embodiment, this is the state with an operative temperature of 20.1° C. At this operative temperature, the difference between KR and KMR shown on the ordinate in FIG. 3 is minimal. According to the most suitable solutions determined by the optimization method, the actuators are then powered accordingly or the heating or cooling panels are temperature-controlled accordingly. The real subject 3 in test environment 1 now has the identical or almost identical thermal comfort perception as the virtual subject in the digital model of room 2.

FIG. 2 further shows that subject 3 wears VR glasses 4, which displays an image of room 2 to the subject depending on his viewing direction, such that subject 3 has the impression to be actually standing in room 2. Thus, the subject also has the identical optical experience of comfort as in room 2 and can, for example, directly experience glare or insufficient lighting when the lighting conditions for his location in room 2 are calculated analogous to the thermal comfort and simulated in the VR glasses.

If different variants of the modernization of room 2 are then simulated, the test environment 1 can be adjusted to a different temperature, for example, in order to allow the effects of a more modern window element 25 or a facade insulation or the reduction of the window opening on the thermal comfort to be experienced. In the case of the reduction of the window opening, subject 3 can, via the VR glasses 4, also simultaneously experience the effect on the lighting of the room or on the view from the window.

As explained in more detail in the illustrated exemplary embodiment for radiant heat and light incidence, test environment 1 can be extended in other exemplary embodiments to consider, for example, the impact of drafts. If, for example, a fan is available as an additional actuator, subject 3 could also experience the effect of an open window. Lastly, in some embodiments of the invention, the subject can also walk virtually around room 2, with the operative temperature θ0 decreasing further as the subject approaches the cold window 25 and increasing again as the subject moves farther away from window 25. Walking around in room 2 can also be simulated in test environment 1 by controlling the actuators accordingly. In the same way as explained above, the effect of different uses or facilities of room 2 or adjacent rooms on the acoustic comfort can be experienced, for example when used as a workshop or open-plan office.

With reference to FIG. 4, the method according to the invention is again explained in more detail in a block diagram, with the parameters applied in FIG. 4 being summarized below:

Overview of parameters in planned room 2

| | |
|---|---|
| RP | =Key figures for room planning |
| | e.g. dimension (height, width, depth) of the planned room, arrangement of active |
| | and passive building components in the planned room, etc. |
| pBK | =Key figures for the static properties of the passive building components in the |
| | planned room |
| | e.g. absorption coefficient of a sound insulation, U-value of a wall. The properties |
| | of passive building components are stored in databases. |
| αBK | =Key figures for the static properties of the active building components in the |
| | planned room |
| | e.g. maximum effectiveness of the active components. The properties of active |
| | building components are stored in databases. |
| P_{αBK} | =Key figures for the current parameters of the active building components in the |
| | planned room. |
| | e.g. noise cancelling system switched on, blinds position, set heating output |
| U_{R} | =Key figures for the external environment of the planned room |
| | e.g. external noise sources, diffuse radiation, relative humidity. U_{R} is largely |
| | determined by the geolocation of the planned room and the prevalent climatic |
| | conditions there, as well as by the time of observation. The key figures for the |
| | external environment are stored in databases. |
| X̅_{R} | =Vector of input variables describing the planned room |
| | X̅_{R} contains RP, pBK, αBK, P_{αBK}, U_{R}. X̅_{R} is the digital twin of the planned room, |
| | i.e. the planned room is described completely on the basis of X̅_{R}. |
| A̅ | =Function physics |
| | Function that describes the physical (especially structural-physical) |
| | interdependencies between input variables (X̅_{R} or X̅_{MR}) and output variables (Y̅_{R} or |
| | Y̅_{MR}). |
| Y̅_{R} | =Vector of output variables that can be measured in the planned room. |
| | Physical parameters |
| B̅ | =Function comfort |
| | Function that describes interdependencies between output variables (Y̅_{R} or Y̅_{MR}) and |
| | comfort variables (K̅_{R} or K̅_{MR}). The relationship between output variables and |
| | comfort variables is determined empirically in experiments and confirmed by large |
| | samples. |
| K̅_{R} | =Vector of comfort variables describing the experience in the planned room. |
| | Comfort variables are indices calculated from the output variables. Comfort |
| | variables describe how a person experiences, i.e. perceives and evaluates a room. |
| | The term “comfort” is used synonymously by a person skilled in the art. Perceived |
| | comfort depends not only on the measurable output variables Y̅, but also on their |
| | interaction. Due to physiological processing, individual output variables are |
| | perceived by humans with different weighting. For example, the four output |
| | variables of room air temperature, wall surface temperature, relative humidity, and |
| | air movement in the room determine thermal comfort, with room air temperature |
| | having the greatest effect. |

Overview of parameters in test environment 1:

| | |
|---|---|
| MRA | =Key figures for setting up test environment 1 |
| | e.g. arrangement of the actuators and distance of the actuators to the subject. |
| Akt | =Key figures for the static properties of the actuators of the test environment |
| | e.g. maximum effectiveness. The properties of the actuators are stored in |
| | databases. |
| P_{Akt} | =Key figures for the current parameters of the actuators of test environment 1 |
| | e.g. set output of the infrared emitters |
| U_{MR} | =Key figures for the immediate environment of test environment 1 |
| | e.g. noise sources, radiation, humidity in the immediate environment of the |
| | subject. U_{MR} describes the initial state prevalent in test environment 1 without |
| | activating the actuators. |
| X̅_{MR} | =Vector of input variables describing the test environment 1 |
| | X̅_{MR} contains MRA, Akt, P_{Akt}, U_{MR}. On the basis of X̅_{R}, the test environment 1, |
| | i.e. the specific implementation of the physical apparatus and its operating state |
| | (“control”) is fully described. |
| A̅ | =Function physics |
| | See above |
| Y̅_{MR} | =Vector of output variables that can be measured in test environment 1 |
| | Physical parameters |
| B̅ | =Function comfort |
| | See above |
| K̅_{MR} | =Vector of comfort variables describing the experience in the test environment |
| | 1. |
| | See above |

In the upper part of the figure, X̅_{R} denotes a vector of input variables describing the planned room 2. These input variables can partly be entered or retrieved from CAD plans, as far as, for example, the geometric dimensions of the room, the orientation of the window areas or the location are concerned. Properties of the passive building components, for example the absorption coefficient of a sound insulation, the U-value of a wall, the effectiveness of a heating element or a ventilation system or other parameters can also be entered by the user or retrieved from a database 5.

To determine the first experience of comfort KR at a predeterminable location in the room, a vector of output variables YR is first determined, which could be measured in the planned room and represent the objective physical properties at the location to be simulated, for example illuminance, air movement, temperature or a sound level. These conditions prevalent in the room can be determined on the basis of the outdoor conditions and the effect of the room, i.e. YR=A·XR.

In the next step, the first experience of comfort KR of the subject is determined by multiplying the objective conditions YR prevalent within the room by a digital comfort model B, i.e. KR=B·YR.

As shown in the lower part of FIG. 4, a similar procedure is performed for test environment 1. The test environment is defined here on the basis of the effectiveness of its actuators and their geometry. This data can also at least in part be retrieved from a database. The objective conditions YMR prevalent within the test environment are thus determined by multiplying the state XMR of the actuators by the digital model AMR of the test environment. The second experience of comfort KMR of the subject in the test environment is determined by multiplying the objective conditions YMR prevalent in the test environment by the digital comfort model B, i.e.

KMR=B·YMR.

As shown in FIG. 3, depending on the state XMR of the actuators, there is a larger or smaller difference Δ(KR, KMR). In an optimization task, the state XMR is then selected as the target wall for the actuators for which the difference Δ is minimal. If the conditions YR prevalent within the room change, for example due to structural changes in room 2, by the influence of heating and ventilation, by opening a window, by switching on/off a lighting device, by having additional people in the room or by other noise or heat sources, the states XMR of the actuators can be tracked, such that these changes in the digital model of room 2 can be experienced by subject 3.

Of course, the invention is not limited to the illustrated embodiments. Therefore, the above description should not be regarded as restrictive but as explanatory. The following claims are to be understood in such a way that a stated feature is present in at least one embodiment of the invention. This does not exclude the presence of further features. If the claims and the above description define “first” and “second” embodiments, this designation is used to distinguish between two similar embodiments without determining a ranking order.

1. A method for simulating an experience of comfort in a room, comprising the following steps:
creating a digital model A of the room;
defining indoor and/or outdoor conditions Y_{R}, X_{R} which act on the room;
calculating a first experience of comfort K_{R} for at least one location within the room;
providing a test environment comprising at least one actuator that acts on a subject; and
changing a state X_{MR} of the at least one actuator such that a second experience of comfort K_{MR} of the subject in the test environment substantially corresponds to the first experience of comfort K_{R} at the at least one location within the room.

2. The method according to claim 1, wherein the at least one actuator is selected from a light source, a monitor, a loudspeaker, headphones, VR glasses, MR glasses, an infrared heater, a cooling panel, a fan, or a device for releasing gaseous or vaporous emissions.

3. The method according to claim 2, wherein the digital model A of the room comprises properties of at least one boundary surface, properties of at least one window, properties of at least one door, properties of at least one heat source in the room, properties of at least one sound source in the room, properties of at least one light source in the room, or properties of at least one source of gaseous emissions in the room.

4. The method according to claim 2, wherein the indoor and/or outdoor conditions are selected from a thermal effect, an illuminance, a sound effect, an air flow, or at least one olfactory stimulus.

5. The method according to claim 1, wherein the calculating the first experience of the comfort K_{R} further comprises:
multiplying the indoor and/or outdoor conditions X_{R} by the digital model A of the room to obtain conditions Y_{R} prevalent within the room; and
multiplying conditions Y_{R} prevalent within the room by a digital comfort model B to determine the first experience of comfort K_{R} of the subject.

6. The method according to claim 1, wherein the second experience of comfort K_{MR} is calculated by:
multiplying the state X_{MR} of at least one actuator by a digital model A_{MR} of the test environment to obtain conditions Y_{MR} prevalent in the test environment; and
multiplying conditions Y_{MR} prevalent in the test environment by the digital comfort model B to determine the second experience of comfort K_{MR} of the subject.

7. The method according to claim 5, wherein the digital comfort model B is determined based on a speech transmission index according to DIN EN IEC 60268-16, a clarity level according to DIN EN ISO 3382-1, a unified glare rating according to DIN EN 12464, a daylight glare probability according to DIN EN 17037, an operative room temperature according to DIN EN ISO 7730, or a radiation asymmetry according to DIN EN ISO 7730.

8. The method according to claim 1, wherein the conditions Y_{MR} are captured by at least one sensor and the state X_{MR} of the at least one actuator is changed according to the sensor signals, further wherein the second experience of comfort K_{MR} of the subject substantially corresponds to the first experience of comfort K_{R} at the at least one location within the room.

9. The method according to claim 1, wherein the subject can influence the indoor and/or outdoor conditions Y_{R}, X_{R} which act on the room.

10. The method according to claim 1, wherein the state X_{MR} of the at least one actuator is retrieved from at least one conversion table according to the desired second experience of comfort K_{MR} of the subject.

11. The method according to claim 1, wherein the state X_{MR} of the at least one actuator is determined by an artificial intelligence according to the desired second experience of comfort K_{MR} of the subject.

12. A non-transitory computer readable storage medium data carrier having data or a signal sequence representing data stored therein representing software executable by a computer, the software including instructions for:
creating a digital model A of the room;
defining indoor and/or outdoor conditions Y_{R}, X_{R} which act on the room;
calculating a first experience of comfort K_{R} for at least one location within the room;
providing a test environment comprising at least one actuator that acts on a subject; and
changing a state X_{MR} of the at least one actuator such that a second experience of comfort K_{MR} of the subject in the test environment substantially corresponds to the first experience of comfort K_{R} at the at least one location within the room.

13. The non-transitory computer readable storage medium of claim 12, wherein the calculating the first experience of the comfort KR further comprises:
multiplying the indoor and/or outdoor conditions X_{R} by the digital model A of the room to obtain conditions Y_{R} prevalent within the room; and
multiplying conditions Y_{R} prevalent within the room by a digital comfort model B to determine the first experience of comfort K_{R} of the subject.

14. The non-transitory computer readable storage medium of claim 13, wherein the the second experience of comfort K_{MR} is calculated by:
multiplying the state X_{MR} of at least one actuator by a digital model A_{MR} of the test environment to obtain conditions Y_{MR} prevalent in the test environment; and
multiplying conditions Y_{MR} prevalent in the test environment by the digital comfort model B to determine the second experience of comfort K_{MR} of the subject.

15. A test environment for simulating an experience of comfort in a room, comprising:
at least one actuator configured to act on a subject, the at least one actuator comprising:
at least one control device configured to influence at least one state X_{MR} of the at least one actuator, wherein the control device is configured to:
store a digital model A of the room;
calculate a first experience of comfort K_{R} for at least one location within the room according to indoor and/or outdoor conditions Y_{R}, X_{R} which act on the room; and
influence the state X_{MR} of the at least one actuator such that the second experience of comfort K_{MR} of the subject substantially corresponds to the first experience of comfort K_{R} at the at least one location within the room.

16. The test environment according to claim 15, wherein the at least one actuator is selected from a light source, a monitor, a loudspeaker, headphones, VR glasses, MR glasses, an infrared heater, a cooling panel, a fan.

17. The test environment according to claim 15, wherein the digital model A of the room is stored in a database and comprises properties of at least one boundary surface, properties of at least one window, properties of at least one door, properties of at least one heat source in the room, properties of at least one sound source in the room, properties of at least one light source in the room, or properties of at least one source of gaseous emissions in the room.

18. The test environment according to claim 15, further comprising:
at least one sensor with which the conditions Y_{MR} prevalent in the test environment can be captured, wherein the control device is configured to change the state X_{MR} of at least one actuator according to the sensor signals such that the second experience of comfort K_{MR} of the subject substantially corresponds to the first experience of comfort K_{R} at the at least one location within the room.

19. The test environment according to claim 15, further comprising:
at least one conversion table from which the state X_{MR} of at least one actuator can be retrieved according to the desired second experience of comfort K_{MR} of the subject.

20. The test environment according to claim 15, further comprising:
at least one artificial intelligence with which the state X_{MR} of at least one actuator can be determined according to the desired second experience of comfort K_{MR} of the subject.
